(19) United States
(12) Patent Application Publication
(10) Pub. No.: US 2012/0031486 A1
(43) Pub. Date: Feb. 9, 2012

(54) Nanoparticle Plasmon Scattering Layer for Photovoltaic Cells

(75) Inventors: J. Wallace Parce, Palo Alto, CA (US); Jian Chen, Sunnyvale, CA (US)

(73) Assignee: NANOSYS, INC., Palo Alto, CA (US)

(21) Appl. No.: 13/264,020

(22) PCT Filed: Apr. 14, 2010
(86) PCT No.: PCT/US10/31085

§ 371 Date: Oct. 12, 2011

Related U.S. Application Data
(60) Provisional application No. 61/172,548, filed on Apr. 24, 2009.
(60) Provisional application No. 61/172,550, filed on Apr. 24, 2009.
(60) Provisional application No. 61/172,553, filed on Apr. 24, 2009.
(60) Provisional application No. 61/172,557, filed on Apr. 24, 2009.

(51) Int. Cl. H01L 31/0216; B05D 5/12; H01L 31/18; B82Y 99/00

(52) U.S. Cl. 136/256; 438/57; 427/108; 977/773; 257/E31.124

(57) ABSTRACT

The present invention relates to nanoparticle compositions for use in photovoltaic cells. Nanoparticles are utilized to provide increased scattering and also wavelength shifting to increase the efficiency of the photovoltaic cells. Exemplary nanoparticles include colloidal metal and fluorescent nanoparticles.

### BACKGROUND OF THE INVENTION

1. Field of the Invention

The present invention relates to nanoparticle compositions for use in photovoltaic cells. Nanoparticles are utilized to provide increased scattering and also wavelength shifting to increase the efficiency of the photovoltaic cells.

2. Background Art

Photovoltaic cells often utilize active area materials such as silicon as photo-absorbing elements. Typically, such materials absorb more strongly in the blue region of the spectrum than in the red to infrared region. Therefore, layers of the photovoltaic cell are often made thicker to absorb (capture) most of the photons in the red region of the solar spectrum. However, if the cells are made thick enough to capture most of the red photons, the efficiency of the absorption of blue photons is compromised. As a result of these two competing effects a compromise is struck in which some of the blue photons are lost to recombination, and some of the red photons are lost to lack of complete absorbance.

Another approach often utilized in photovoltaic cells is to make the cells thinner, thereby allowing for separation of the hole electron pairs produced by the blue photos, and to roughen the interfaces of the various layers of the cell so as to cause the red photons to travel at angles that increase their path length through the active layers of the cell, thereby increasing absorbance. However, this surface roughening also causes more recombination sites to be produced at the layer interfaces and enhances hole electron recombination, reducing the photocurrent, and is also a costly and time-consuming process.

What is needed therefore are compositions and methods that can simultaneously increase the solar response of both blue and near ultra violet (UV) photons, as well as red and near-infrared photons, of the solar spectrum, thereby increasing the efficiency of the photovoltaic cell.

### BRIEF SUMMARY OF THE INVENTION

The present invention fulfills these need by providing compositions and methods comprising various metallic and fluorescent nanoparticles. The nanoparticles provide both conversion of blue photons to longer wavelengths and scattering of red photons.

In an embodiment, the present invention provides compositions comprising one or more colloidal metal nanoparticles, wherein the compositions are disposed on a substantially transparent substrate of a photovoltaic cell. Suitably, the colloidal metal nanoparticles comprise Ag, Au, Cu or Al, and are about 50 nm to about 800 nm in size, about 100 nm to about 800 nm in size, or about 200 nm to about 800 nm in size. The colloidal metal nanoparticles are suitably spherical, hemispherical, cylindrical or disk-shaped.

In exemplary embodiments, the compositions comprise a dielectric material encapsulating the colloidal metal nanoparticles, such as a spin-on-glass material.

Suitably, the compositions further comprise one or more fluorescent nanoparticles. The compositions can comprise a single layer comprising the metal nanoparticles and the fluorescent nanoparticles, or can comprise at least two layers, wherein the colloidal metal nanoparticles and the fluorescent nanoparticles are in separate layers.

Exemplary the fluorescent nanoparticles for use in the practice of the present invention include, but are not limited to, CdSe, ZnSe, ZnTe and InP nanoparticles. Suitably, the fluorescent nanoparticles comprise a core selected from the group consisting of CdSe, ZnSe, ZnTe and InP, and a shell selected from the group consisting of ZnS and CdS surrounding the core. Suitably, the core is doped with Mn or Cu. In exemplary embodiments, the core is about 1 nm to about 6 nm in size, and the shell is less than about 2 nm in thickness, suitably about 1 Å to about 10 Å in thickness.

In exemplary embodiments, the transparent substrate comprises glass. In further embodiments, the photovoltaic cell comprises one or more hydrogenated amorphous silicon layers. Suitably the photovoltaic cell comprises one or more hydrogenated amorphous silicon layers, and one or more hydrogenated microcrystalline or hydrogenated nanocrystalline silicon layers.

Suitably, interfaces between the hydrogenated amorphous silicon layers (including interfaces between the one or more hydrogenated microcrystalline or hydrogenated nanocrystalline silicon layers) are substantially non-textured, and in further embodiments, interfaces between the hydrogenated amorphous silicon layers, and interfaces between the hydrogenated amorphous silicon layers and an electrode of the photovoltaic cell, are substantially non-textured.

Suitably, the compositions comprise a substantially transparent substrate disposed on the composition of colloidal nanoparticles.

In exemplary embodiments, the compositions comprise Ag colloidal nanoparticles and ZnTe or CdSe nanoparticles.

Additional features and advantages of the invention will be set forth in the description that follows, and in part will be apparent from the description, or may be learned by practice of the invention. The advantages of the invention will be realized and attained by the structure and particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1A shows a composition of the present invention disposed on the substantially transparent substrate of a photovoltaic cell.

FIG. 1B shows a composition of the present invention prepared as a single layer.

FIG. 1C shows a composition of the present invention prepared as multiple layers.

FIG. 2 shows a method of preparing a photovoltaic cell in accordance with one embodiment of the present invention.

The present invention will now be described with reference to the accompanying drawings. In the drawings, like reference numbers indicate identical or functionally similar elements.

### DETAILED DESCRIPTION OF THE INVENTION

It should be appreciated that the particular implementations shown and described herein are examples of the invention and are not intended to otherwise limit the scope of the present invention in any way. Indeed, for the sake of brevity, conventional electronics, manufacturing, semiconductor devices, and nanocrystal, nanoparticle, nanowire (NW), nanorod, nanotube, and nanoribbon technologies and other functional aspects of the systems (and components of the individual operating components of the systems) may not be described in detail herein. Further, the techniques are suitable for applications in electrical systems, optical systems, consumer electronics, industrial or military electronics, wireless systems, space applications, or any other application.

As used herein, the term “nanoparticle” refers to a particle that has at least one region or characteristic dimension with a dimension of less than about 500 nm, including on the order of less than about 1 nm. The term “nanoparticle” as used herein encompasses quantum dots, nanocrystals, nanowires, nanorods, nanoribbons, nanotetrapods and other similar nanostructures known to those skilled in the art. As described throughout, nanoparticles (e.g., nanocrystals, quantum dots, nanowires, etc.), suitably have at least one characteristic dimension less than about 500 nm. Suitably, nanoparticles are less than about 500 nm, less than about 300 nm, less than about 200 nm, less than about 100 nm, less than about 50 nm, less than about 20 nm, less than about 15 nm, less than about 10 nm or less than about 5 nm in at least one characteristic dimension (e.g., the dimension across the width or length of the nanoparticle). Examples of nanowires include semiconductor nanowires as described in Published International Patent Application Nos. WO 02/17362, WO 02/48701, and WO 01/03208, carbon nanotubes, and other elongated conductive or semiconductive structures of like dimensions.

Typically, the region of characteristic dimension is along the smallest axis of the structure. Nanoparticles for use in the present invention include those that substantially the same size in all dimensions, e.g., substantially spherical, as well as non-spherical structures, including hemispherical, cylindrical and disk-shaped. Nanoparticles can be substantially homogenous in material properties, or in certain embodiments, can be heterogeneous. The optical properties of nanoparticles can be determined by their particle size, chemical or surface composition. The present invention provides the ability to tailor nanoparticle size in the range between about 1 nm and about 800 nm, although the present invention is applicable to other size ranges of nanoparticles.

Nanoparticles for use in the present invention can be produced using any method known to those skilled in the art. Suitable methods are disclosed in U.S. patent application Ser. No. 11/034,216, filed Jan. 13, 2005, U.S. patent application Ser. No. 10/796,832, filed Mar. 10, 2004, U.S. patent application Ser. No. 10/656,910, filed Sep. 4, 2003, U.S. Provisional Patent Application No. 60/578,236, filed Jun. 8, 2004, and U.S. patent application Ser. No. 11/506,769, filed Aug. 18, 2006, the disclosures of each of which are incorporated by reference herein in their entireties. The nanoparticles for use in the present invention can be produced from any suitable material, including organic material, inorganic material, such as inorganic conductive materials (e.g., metals), semiconductive materials and insulator materials. Suitable semiconductor materials include those disclosed in U.S. patent application Ser. No. 10/796,832 and include any type of semiconductor, including group II-VI, group III-V, group IV-VI and group IV semiconductors. Suitable semiconductor materials include, but are not limited to, Si, Ge, Sn, Se, Te, B, C (including diamond), P, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, (Al, Ga, In)₂ (S, Se, Te)₃, Al₂CO, and an appropriate combination of two or more such semiconductors. Suitable metals include, but are not limited to, Group 10 atoms such as Pd, Pt or Ni, as well as other metals, including but not limited to, W, Ru, Ta, Co, Mo, Ir, Re, Rh, Hf, Nb, Au, Ag, Fe, and Al. Suitable insulator materials include, but are not limited to, SiO₂, TiO₂ and Si₃N₄.

The nanoparticles useful in the present invention can also further comprise ligands conjugated, associated, or otherwise attached to their surface as described throughout. Suitable ligands include any group known to those skilled in the art, including those disclosed in (and methods of attachment disclosed in) U.S. patent application Ser. No. 10/656,910, U.S. patent application Ser. No. 11/034,216, and U.S. Provisional Patent Application No. 60/578,236, the disclosures of each of which are hereby incorporated by reference herein for all purposes. Use of such ligands can enhance the ability of the nanoparticles to associate and spread on various material surfaces. In addition, such ligands act to keep the individual nanoparticles separate from each other so that they do not aggregate together prior to or during application.

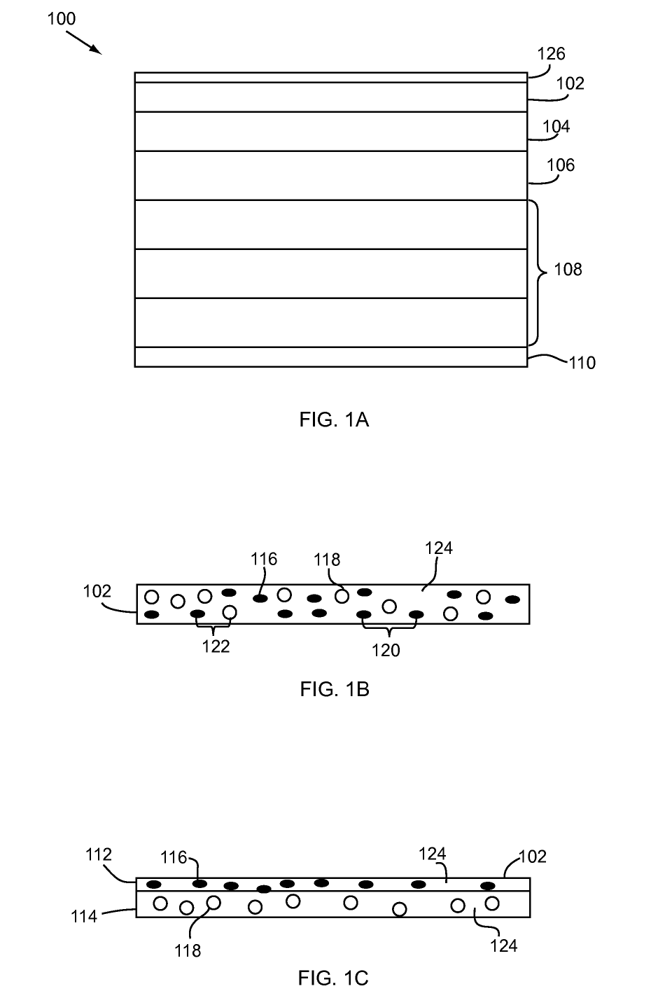

In exemplary embodiments, the present invention provides compositions comprising one or more colloidal metal nanoparticles (also called colloidal metallic nanoparticles). As shown in FIGS. 1A-1C, the compositions 102 are disposed on a transparent substrate 104 of a photovoltaic cell 100. Photovoltaic cells 100 of the present invention suitably comprise a transparent substrate 104, a front contact electrode 106, one or more photovoltaic module semiconductors 108, and a back contact electrode 110. Examples of these elements (104, 106, 108 and 110) of the photovoltaic cells are well known in the art, and disclosed for example, in U.S. Pat. Nos. 4,064,521, 4,718,947, 4,718,947 and 5,055,141, the disclosures of which are incorporated by reference herein in their entireties.

As used herein, the term “colloidal metal nanoparticles” 118 refers to metal nanoparticles formed using solution chemistry that are then dispersed in solution prior to deposition on a substrate. The colloidal metal nanoparticles 118 remain suspended in solution and do not substantially aggregate or dissolve prior to deposition. The colloidal metal nanoparticles of the present invention, are distinguished from metal nanoparticles that are deposited using chemical vapor deposition (CVD) or physical vapor deposition (PVD) followed by heating to generate the nanoparticles on the substrate. The colloidal metal nanoparticles for use in the practice of the present invention do not require the use of CVD or PVD for deposition, and also do not require the use of elevated temperatures, thereby reducing the time, cost and complexity of formation of the compositions of the present invention.

As used herein, the colloidal metal nanoparticles 118 are disposed on transparent substrate 104 of photovoltaic cell 100 such that they at least partially cover the surface of transparent substrate 104, and suitably, are disposed across at least about 30%, more suitably at least about 40%, at least about 50%, at least about 60%, at least about 70%, at least about 80% or at least about 90% of the surface of transparent substrate 104. Methods for disposing the colloidal metal nanoparticles 118 on transparent substrate 104 are described throughout and known in the art.

Suitably transparent substrate 104 of photovoltaic cell 100 is substantially transparent (and in exemplary embodiments comprises glass or a polymer). As used herein “substantially transparent” means that the substrate of the photovoltaic cell allows the transmission of greater than about 50% of the photons which enter the substrate to pass through the substrate to the remaining layers/elements of the photovoltaic cell. Suitably, the substantially transparent substrates of the present invention allow greater than about 75%, greater than about 80%, greater than about 90%, greater than about 95% or about 100% of the photons which enter the substrate to pass through the substrate.

It should be understood that the terms “photovoltaic cells” and “solar cells” are used interchangeably throughout and refer to devices that convert sunlight/solar energy or other sources of light directly into electricity by the photovoltaic effect. Assemblies of photovoltaic cells can be used to make solar panels, solar modules, or photovoltaic arrays. Exemplary components and designs of photovoltaic cells are described throughout and also well known in the art.

Exemplary metallic nanoparticles which can be used as the colloidal metal nanoparticles are described throughout. Suitably, the colloidal metal nanoparticles comprise Ag, Au, Cu or Al, as well as combinations and alloys of these metals. Suitably, the colloidal metal nanoparticles are Ag colloidal nanoparticles.

Suitably, the sizes of the colloidal metal nanoparticles for use in the practice of the present invention are about 10 nm to about 1 μm in size, more suitably about 30 nm to about 800 nm, about 50 nm to about 800 nm, about 100 nm to about 800 nm, about 200 nm to about 800 nm, or about 100 nm, about 200 nm, about 300 nm, about 400 nm, about 500 nm, about 600 nm, about 700 nm or about 800 nm in size, including any value or range within these size ranges.

In exemplary embodiments, the colloidal metal nanoparticles 118 can be hemispherical, cylindrical, disk-shaped, or can be spherical, or the compositions can comprise combination of such shapes. Hemispherical refers to structures that have a shape that is approximately one-half of a sphere. Disk-shaped refers to structures that have a substantially circular cross-section that is larger than the overall height of the structures. Exemplary methods of preparing disk-shaped metal nanoparticles are disclosed, for example, in Chen et al., “Silver Nanodisk: Synthesis, Characterization and Self-Assembly,” Materials Research Society, Fall 2002 Symposium, Paper I10.11 (2002), and Hägglund et al., “Electromagnetic coupling of light into a silicon solar cell by nanodisk plasmons,” Applied Physics Letters 92:053110-1 to 053110-3 (2008), the disclosures of which are incorporated by reference herein in their entireties.

Additional methods of preparing the colloidal metal nanoparticles of the present invention are disclosed in U.S. Pat. Nos. 5,491,114; 5,576,248; 6,268,041; 7,267,875; 7,501,315; 6,723,606; and 6,586,785; Published U.S. Patent Application Nos. 2008/0032134; 2008/0118755; 2009/0065764; and 2007/0032091; and Published International Patent Application No. WO 2007/024697, the disclosures of each of which are incorporated by reference herein in their entireties for all purposes.

In suitable embodiments, the compositions comprise a dielectric material 124 encapsulating the colloidal metal nanoparticles 118. This dielectric material suitably forms an ink, solution or suspension in which the colloidal metal nanoparticles are dispersed, thus allowing simple deposition, spreading and application of the compositions of the present invention. Exemplary dielectric materials include, but are not limited to, Si-comprising materials, SiO₂, spin-on-glass materials (e.g., silicates, siloxanes, phosphosilicates), SiN, and other dielectric materials known in the art.

Suitably, the compositions 102 of the present invention further comprise one or more fluorescent nanoparticles 116. Exemplary fluorescent nanoparticles for use in the compositions include, but are not limited to, semiconductor materials including those disclosed in U.S. patent application Ser. No. 10/796,832 including any type of semiconductor, including group II-VI, group III-V, group IV-VI and group IV semiconductors. Suitably, the fluorescent nanoparticles comprise materials such as, but are not limited to, Si, Ge, Sn, Se, Te, B, C (including diamond), P, BN, BP, BAs, MN, AlP, AlAs, AlSb, GaN, GaP, GaAs, GaSb, InN, InP, InAs, InSb, MN, AlP, AlAs, AlSb, GaN, GaP, GaAs, GaSb, ZnO, ZnS, ZnSe, ZnTe, CdS, CdSe, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, (Al, Ga, In)₂ (S, Se, Te)₃, Al₂CO, and an appropriate combination of two or more such semiconductors. In exemplary embodiments, the compositions comprise fluorescent nanoparticles comprising CdSe, ZnSe, ZnTe, or InP nanoparticles, as well as combinations of such nanoparticles.

Suitably, the fluorescent nanoparticles comprise a core/shell structure. In semiconductor nanoparticles, photo-induced emission arises from the band edge states of the nanoparticles. The band-edge emission from fluorescent/luminescent nanoparticles competes with radiative and non-radiative decay channels originating from surface electronic states. X. Peng, et al., J. Am. Chem. Soc. 30:7019-7029 (1997). As a result, the presence of surface defects such as dangling bonds provide non-radiative recombination centers and contribute to lowered emission efficiency. An efficient and permanent method to passivate and remove the surface trap states is to epitaxially grow an inorganic shell material on the surface of the nanoparticle. X. Peng, et al., J. Am. Chem. Soc. 30:7019-7029 (1997). The shell material can be chosen such that the electronic levels are type I with respect to the core material (e.g., with a larger bandgap to provide a potential step localizing the electron and hole to the core). As a result, the probability of non-radiative recombination can be reduced.

Core-shell structures are obtained by adding organometallic precursors containing the shell materials to a reaction mixture containing the core nanoparticle. In this case, rather than a nucleation-event followed by growth, the cores act as the nuclei, and the shells grow from their surface. The temperature of the reaction is kept low to favor the addition of shell material monomers to the core surface, while preventing independent nucleation of nanoparticles of the shell materials. Surfactants in the reaction mixture are present to direct the controlled growth of shell material and ensure solubility. A uniform and epitaxially grown shell is obtained when there is a low lattice mismatch between the two materials. Additionally, the spherical shape acts to minimize interfacial strain energy from the large radius of curvature, thereby preventing the formation of dislocations that could degrade the optical properties of the nanoparticle system.

Exemplary core-shell fluorescent nanoparticles for use in the practice of the present invention include, but are not limited to, (represented as Core/Shell), CdSe/ZnS, CdSe/CdS, ZnSe/ZnS, ZnSe/CdS, ZnTe/ZnS, ZnTe/CdS, InP/ZnS, InP/CdS, PbSe/PbS, CdTe/CdS, CdTe/ZnS, as well as others. In further embodiments, the nanoparticles can comprise a core/shell/shell structure, such as CdSe/CdS/ZbS. In such embodiments, the Cd in the intermediate shell layer (CdS), while probably not a complete monolayer, is thought to relieve stress from the lattice mismatch between CdSe and ZnS. Suitably, the core of the fluorescent nanoparticles are doped. Exemplary dopants which can be utilized in the practice of the present invention include Mn and Cu, as well as other elements. Suitably, the fluorescent nanoparticles comprise ZnTe or ZnSe core nanoparticles doped with Mn or Cu.

In exemplary embodiments, the core of the fluorescent nanoparticles are about 0.5 nm to about 20 nm in size, suitably about 1 nm to about 15 nm, about 1 nm to about 10 nm, about 1 nm to about 8 nm, or about 1 nm to about 6 nm in size, for example about 1 nm, about 2 nm, about 3 nm, about 4 nm, about 5 nm, about 6 nm, about 7 nm, about 8 nm, about 9 nm or about 10 nm. Suitably, the thickness of the shell surrounding the core of the fluorescent nanoparticles is less than about 5 nm in thickness, suitably, less than about 4 nm, less than about 3 nm, less than about 2 nm, or less than about 1 nm in thickness. In exemplary embodiments, the shell surrounding the core of the fluorescent nanoparticles is about 1 Å to about 20 Å in thickness, 1 Å to about 15 Å in thickness, or about 1 Å to about 10 Å in thickness.

As shown in FIG. 1B, the compositions 102 of the present invention can suitably comprise a single layer comprising the colloidal metal nanoparticles 118 and the fluorescent nanoparticles 116. It should be understood that the size, distribution, density and arrangement of colloidal metal nanoparticles 118 and fluorescent nanoparticles 116 is provided for illustrative purposes only. In further embodiments, as shown in FIG. 1C, the compositions 102 of the present invention comprise at least two layers 112, 114, wherein the colloidal metal nanoparticles 118 and the fluorescent nanoparticles 116 are in separate layers, 114 and 112, respectively. In embodiments where the compositions comprise at least two layers, suitably the dielectric material 124 comprising the two layers is the same, though in other embodiments, different dielectric materials can be utilized for the layer 114 comprising the colloidal metal nanoparticles 118 and the layer 112 comprising the fluorescent nanoparticles 116.

It should be noted, in suitable embodiments, when two separate layers are utilized, the fluorescent nanoparticles are suitably in a layer that is “above” the layer comprising that colloidal metal nanoparticles. That is, when layer 112 is part of a photovoltaic cell, photons of light impact fluorescent nanoparticles 116 before entering the layer 114 comprising the colloidal metal nanoparticles 118. However, opposite orientation can also be used in which layer 114 comprising colloidal metal nanoparticles 118 can be on top of layer 112 comprising the fluorescent nanoparticles 116. While in exemplary embodiments, the nanoparticles are in two separate layers, any number of layers can be utilized including layers that do not comprise any nanoparticles (i.e., are transparent) between the layers comprising the nanoparticles, or a transparent layer(s) between the nanoparticle-comprising layers and the photovoltaic cell. In further embodiments, multiple layers that comprise both the fluorescent nanoparticles and the colloidal metal nanoparticles can also be used.

In embodiments, the fluorescent nanoparticles 116 are present at a packing density in the compositions. As used herein, “packing density” refers to the proximity of the fluorescent nanoparticles and/or the colloidal metal nanoparticles to each other. FIG. 1B shows as representation of the average distance, 120, between the fluorescent nanoparticles. As used herein, “average distance” refers to the mean distance between the center of two adjacent nanoparticles (whether they be fluorescent or colloidal metal), taking into account fluctuations over time in the distance between the nanoparticles. The packing density of the nanoparticles (fluorescent and/or colloidal nanoparticles) is readily controlled by one of ordinary skill in the art by selecting the appropriate concentration of nanoparticles per volume or surface area that is to be covered. As the nanoparticles suitably remain dispersed in any carrier material (e.g., dielectric), the packing density will be maintained following deposition.

In exemplary embodiments, an average 120 distance between the fluorescent nanoparticles 116 is less than a Foerster distance (R₀) of the fluorescent nanoparticles. This density can be achieved when the fluorescent nanoparticles 116 are in the same layer (i.e., FIG. 1B) or different layers (i.e., FIG. 1C) as the colloidal metal nanoparticles 118. In further embodiments, the average distance 120 between the flourescent nanoparticles 116 can be equal to, or greater than, the Foerster distance of the fluorescent nanoparticles.

The Forester distance (R₀), refers to the distance at which the fluorescent resonance energy transfer (FRET) is 50% efficient, that is, the distance where 50% of the excited donors are deactivated by FRET. At R₀, there is an equal probability for resonance energy transfer and the radiative emission of a photon. The magnitude of R₀ is readily calculated by those of ordinary skill in the art based on the characteristics of the fluorescent nanoparticles and the surrounding medium (e.g., dielectric).

As shown in FIGS. 1B and 1C, the fluorescent nanoparticles can be maintained at the desired packing density in both single, and multiple-layer configurations. In embodiments, where both the fluorescent nanoparticles 116 and the colloidal metal nanoparticles 118 are present in the same layer of the composition, the fluorescent nanoparticles and the metal nanoparticles are at packing density such that the average distance 120 between the fluorescent nanoparticles 116 is less than, equal to, or greater than the Foerster distance of the fluorescent nanoparticles, and the average distance 122 between the fluorescent nanoparticles 116 and the metal nanoparticles 118 is less than, equal to, or greater than, the Foerster distance of the fluorescent nanoparticles. It should be noted, however, that the average distance 122 between the fluorescent nanoparticles 116 and the colloidal metal nanoparticles 118 can also be maintained in embodiments where the fluorescent nanoparticles 116 and the colloidal metal nanoparticles 118 are in different layers (112 and 114, respectively), as in FIG. 1C.

In further embodiments, the compositions of the present invention can comprise two different colloidal metal nanoparticles (i.e., two different popullations of colloidal metal nanoparticles, and thus two different surface plasma resonance frequencies). For example, in suitable embodiments, the plasma resonance frequency of one populations of colloidal metal nanoparticles overlaps with the emission wavelength of the fluorescent nanoparticles, and the plasma frequency of another population of colloidal metal nanoparticles is in the red or near infra-red so as to scatter longer wavelength photons.

The photovoltaic cell on which the compositions of the present invention are disposed further comprises a photovoltaic module semiconductor, such as one or more hydrogenated amorphous silicon (a-Si) layers. See for example, U.S. Pat. Nos. 4,064,521, 4,718,947, 4,718,947 and 5,055,141, the disclosures of which are incorporated by reference herein in their entireties, which disclose photovoltaic cells that comprise a-Si, as well as methods of preparing such cells. As shown in FIG. 1A, suitably such hydrogenated amorphous silicon layers comprise three separate layers, suitably positively-doped (p), intrinsic (i) and negatively doped (n), which form a p-i-n junction (see U.S. Pat. No. 5,055,141). Such three-layer semiconductors are well known in the photovoltaic cell art. In exemplary embodiments, the photovoltaic cells comprise one or more hydrogenated amorphous silicon layers and one or more hydrogenated microcrystalline (μc-Si) or hydrogenated nanocrystalline silicon (nc-Si) layers. Such cells are often referred to as “micro-morph” cells (see, e.g., U.S. Pat. No. 6,309,906, the disclosure of which is incorporated by reference herein in its entirety). The compositions described herein can be utilized with a-Si or micro-morph photovoltaic cells, crystalline-Si photovoltaic cells, CdTe cells, as well as CIGS photovoltaic cells, as described herein below and known in the art.

Use of the compositions of the present invention on transparent substrates of photovoltaic cells allows the interfaces between the hydrogenated amorphous silicon layers of these cells to be substantially non-textured. As used herein, “interface” refers to the common boundary between two surfaces, such as between each of the p-i-n layers of a semiconductor material, or between the semiconductor material and an electrode (front and/or back 104/110) of the photovoltaic cell. As noted above, in traditional photovoltaic cells, it is common to texture or roughen the interfaces between the different semiconductor layers of the photovoltaic cells, as well as the interface between the semiconductors and the top and/or bottom electrode of the photovoltaic cell. This texturing has traditionally been used to increase the amount of scattering when photons enter the semiconductor region of the photovoltaic cell, thereby increasing the amount of absorption of the photons (especially the red wavelengths). However, texturing requires an additional manufacturing step which can be time consuming and costly.

The compositions of the present invention provide for increased light scattering by the plasmonics effect (plasmon resonance or plasmonic scattering) of the colloidal metallic nanoparticles. See e.g., Catchpole et al., “Plasmonic solar cells,” Optics Express 16:21793-21800 (2008). Thus, the interfaces between the various semiconductor materials and the interfaces between the semiconductor materials and the electrodes of a photovoltaic cell do not need to be textured. Thus, in suitable embodiments of the present invention, the interfaces between the hydrogenated amorphous silicon layers, and interfaces between the hydrogenated amorphous silicon layers and an electrode (e.g., the top and/or bottom electrode) of the photovoltaic cell, are substantially non-textured. In additional embodiments, the interfaces between the hydrogenated amorphous silicon layers, and interfaces between the one or more hydrogenated microcrystalline or hydrogenated nanocrystalline silicon layers, and interfaces between the hydrogenated silicon layers and an electrode of the photovoltaic cell are substantially non-textured. As used herein, the term “non-textured” refers to an interface which is substantially planar or smooth, and suitably, has a surface roughness that is less than about 1 μm. It should be noted, however, that the compositions of the present invention can be utilized with photovoltaic cells in which the various interfaces noted above are textured.

In exemplary embodiments, the compositions of the present invention further comprise a substantially transparent substrate 126 (e.g., glass or polymeric) disposed on the composition of colloidal nanoparticles 102. As shown in FIG. 1A, suitably transparent substrate 126 is disposed on compositions 102 opposite electrode 104. Transparent substrate 126 helps to protect the nanoparticles (both colloidal metallic and fluorescent) from damage and oxidation by O₂ and/or H₂O in the surrounding environment, as well as physical or environmental damage during use in photovoltaic modules and arrays. As described herein, suitably the compositions 102 of the present invention are disposed on the transparent substrate 104 of a photovoltaic cell opposite the electrode 106. In further embodiments, the compositions can be disposed between the transparent substrate 104 and the electrode 106. In still further embodiments, the compositions can be sandwiched between two substantially transparent substrates (e.g., glass or polymeric sheets or plates), and then this sandwiched structure can be disposed on the transparent substrate 102 of the photovoltaic cell 100 either opposite the electrode 106, or between the electrode 106 and the transparent substrate 104. In additional embodiments, the colloidal metal nanoparticles can also be encapsulated in the electrode 106 itself (i.e., a transparent conductive oxide).

In suitable embodiments, the compositions of the present invention comprise Ag colloidal nanoparticles and ZnTe fluorescent nanoparticles, suitably doped with Mn or Cu.

The present invention also provides methods of preparing a composition 102 comprising one or more colloidal metal nanoparticles 118 on a substantially transparent substrate 104 of a photovoltaic cell 100. The methods suitably comprise providing a substantially transparent substrate 104 and disposing a composition 102 comprising a dielectric material and colloidal metal nanoparticles 118 on the substantially transparent substrate. Suitably, the methods comprise disposing a composition further comprising one or more fluorescent nanoparticles 116 on the substrate.

As used herein, suitably the transparent substrate comprises glass or a polymer. Exemplary metallic nanoparticles (e.g., Ag) and fluorescent nanoparticles are described herein, as are suitable sizes, shapes and core/shell structures for the various nanoparticles. The methods suitably comprise disposing the compositions comprising colloidal metallic nanoparticles and fluorescent nanoparticles in the same layer (e.g., FIG. 1B), though in other embodiments, the colloidal metallic nanoparticles and fluorescent nanoparticles are disposed in separate layers (including two or more layers) (e.g., FIG. 1C).

Suitably, the compositions are disposed in a spin-on glass material. As used herein disposing includes any suitable method of depositing the compositions on the transparent substrate and includes, for example, spin coating, ink jet printing, drop-casting, spraying, screen printing, layering, spreading, painting, dip-coating, etc., the compositions.

In suitable embodiments, following disposing of the compositions (for example, nanoparticles in a spin-on-glass material), the compositions are suitably annealed so as to burn off the hydrocarbon constituents of the compositions, and to convert the dielectric material to a solid, e.g., glass, structure. In embodiments where both the colloidal metal nanoparticles and the fluorescent nanoparticles are disposed in a single layer, the annealing is suitably performed in an inert environment (e.g., under an inert gas) so as to prevent the fluorescent nanoparticles from being oxidized. In embodiments where two (or more) separate layers are used, the composition comprising the fluorescent nanoparticles is suitably annealed under and inert atmosphere. Then, the composition of colloidal metallic nanoparticles is disposed, following by a second annealing, which can be in either an inert atmosphere, or in air or oxygen. Suitably, the compositions are annealed at a relatively low temperature, i.e., below about 500° C., suitably below about 400° C., below about 300° C. or below about 200° C.

In further embodiments, the colloidal metal nanoparticles are disposed with one or more ligands associated with each nanoparticle (i.e., a coated nanoparticle). Following the disposing of the nanoparticles, the ligand is cured to generate a dielectric shell surrounding each nanoparticle, as disclosed in Published U.S. Patent Application No. 2006/0040103, the disclosure of which is incorporated by reference herein in its entirety. Briefly, nanoparticles for use in this embodiment of the present invention differ from nanoparticles embedded in a matrix (e.g., dielectric), in that each coated nanoparticle has, upon synthesis or after subsequent application, a defined boundary provided by the coating that is not contiguous with the surrounding matrix. For ease of discussion, the coating material is generally referred to in U.S. Patent Application No. 2006/0040103 as a “ligand” in that such coating typically comprises molecules that have individual interactions with the surface of the nanostructure, e.g., covalent, ionic, van der Waals, or other specific molecular interactions. As described in Published U.S. Patent Application No. 2006/0040103, the first coatings are converted to second coatings such that the individual nanoparticles are not in direct contact with each other. Furthermore, the second coating (shell) component of the coated nanostructure is often non-crystalline.

Discrete coated nanoparticles for use in the practice of the present invention include an individual nanoparticle having a first surface and a first coating associated with the first surface of the individual nanoparticle and having a first optical, electrical, physical or structural property, wherein the first coating is capable of being converted to a second coating having a different electrical, optical, structural and/or other physical property than the first coating. In some embodiments, the first coating encapsulates the nanoparticle (i.e., it completely surrounds the nanoparticle being coated). In other embodiments, the nanoparticle is partially encapsulated.

As discussed in Published U.S. Patent Application No. 2006/0040103 in certain embodiments, the coated nanoparticle includes a silicon oxide cage complex (e.g., a silsesquioxane composition) as the first coating. The silsesquioxane can be either a closed cage structure or a partially open cage structure. Optionally, the silicon oxide cage complex (e.g., the silsesquioxane) is derivatized with one or more boron, methyl, ethyl, branched or straight chain alkanes or alkenes with 3 to 22 (or more) carbon atoms, isopropyl, isobutyl, phenyl, cyclopentyl, cyclohexyl, cycloheptyl, isooctyl, norbornyl, and/or trimethylsilyl groups, electron withdrawing groups, electron donating groups, or a combination thereof. In an alternate embodiment, discrete silicates are employed in the first coating composition. One discrete silicate which can be used as first coatings is phosphosilicate. Upon curing, the silicon oxide cage complex first coating is typically converted to a second rigid coating comprising a silicon oxide (e.g., SiO2). Methods of curing the ligand coatings are described throughout U.S. Patent Application No. 2006/0040103. Curing is typically achieved at temperatures less than about 500° C. In some embodiments, the heating process is performed between 200-350° C. As described throughout U.S. Patent Application No. 2006/0040103, the curing process results in the formation of the second coating or shell (e.g., a thin, solid matrix on the first surface of the nanoparticle). Suitably, the second coating is a rigid insulating shell comprising a glass or glass-like composition, such as SiO₂.

As described herein, suitably the fluorescent nanoparticles are disposed at a packing density such that the average distance 120 between the fluorescent nanoparticles 116 is less than, equal to, or greater than a Foerster distance of the fluorescent nanoparticles. In further embodiments, the fluorescent nanoparticles 116 and the metal nanoparticles 118 are disposed at a packing density such that an average distance 120 between the fluorescent nanoparticles is less than, equal to, or great than, a Foerster distance of the fluorescent nanoparticles, and an average distance 122 between the fluorescent nanoparticles and the metal nanoparticles is less than, equal to, or great than, the Foerster distance of the fluorescent nanoparticles.

Suitably, the methods of the present invention further comprise disposing a substantially transparent substrate 126 (e.g., a glass or polymer substrate) on the composition of metal colloidal nanoparticles. This transparent substrate helps to protect the nanoparticles from oxidation as well as other environmental damage.

In further embodiments, the present invention provides photovoltaic cells 100. Suitably, photovoltaic cell 100 comprises a substantially transparent substrate 104, and a composition 102 comprising one or more colloidal metal nanoparticles 118 disposed on the substrate 104. Exemplary colloidal metal nanoparticles 118 are described throughout, and include, Ag, Au, Cu and Al colloidal metal nanoparticles. Exemplary sizes, compositions and shapes of the colloidal metal nanoparticles are described herein.

As described herein, suitably the compositions 102 comprise a dielectric material 124 encapsulating the colloidal metal nanoparticles 118, and suitably, a spin-on glass material. As described herein, suitably the compositions 102 further comprise one or more fluorescent nanoparticles 116, either in a single layer (e.g., FIG. 1B) or in multiple layers (e.g., FIG. 1C), wherein the colloidal metal nanoparticles 118 and the fluorescent nanoparticles 116 are in separate layers (112/114).

Exemplary fluorescent nanoparticles are described herein, and suitably are CdSe, ZnSe, ZnTe or InP nanoparticles, including fluorescent nanoparticles comprising a core of CdSe, ZnSe, ZnTe and InP, and a shell of ZnS and CdS surrounding the core. In exemplary embodiments, the core is doped with Mn or Cu. Exemplary thickness of the core and shell of the fluorescent nanoparticles are described throughout.

As described herein, suitably the fluorescent nanoparticles are at a packing density such that the average distance between the fluorescent nanoparticles is less than, equal to, or greater than, a Foerster distance of the fluorescent nanoparticles. Suitably the fluorescent nanoparticles and the metal nanoparticles are at packing density such that an average distance between the fluorescent nanoparticles is less than, equal to, or greater than, a Foerster distance of the fluorescent nanoparticles. In further embodiments, the average distance between the fluorescent nanoparticles and the metal nanoparticles is less than, equal to, or greater than, the Foerster distance of the fluorescent nanoparticles.

As shown in FIG. 1A suitably, the photovoltaic cells 100 of the present invention further comprise a back contact electrode 110. Exemplary materials for use as back contact electrode 110 are known in the art, and include aluminum, tin oxide or zinc oxide. Suitably, a photovoltaic module semiconductor 108 is disposed on the back contact electrode.

As used herein, “photovoltaic module semiconductor” 108 refers to semiconductor materials that can be used to generate a photovoltaic effect—i.e., the conversion of solar light to electric current. Suitably, photovoltaic module semiconductors for use in the practice of the present invention comprise one or more hydrogenated amorphous silicon (a-Si) layers (e.g., as a p-i-n layered stack). In further embodiments, the photovoltaic module semiconductor 108 comprises one or more hydrogenated amorphous silicon layers and one or more hydrogenated microcrystalline or hydrogenated nanocrystalline silicon layers, so as to form a “micro-morph” photovoltaic cell, as described herein. Additional materials which can be utilized as the photovoltaic module semiconductor include crystalline Si, CdTe, as well as “CIGS” materials, or semiconductor materials comprising copper-indium-diselenide (CuInSe₂) and/or copper-indium-gallium-diselenide (CuIn₁₋ₓGaₓSe₂), both of which are generically referred to as Cu(In,Ga)Se₂, CIGS, or simply CIS herein and in the art.

In exemplary embodiments, the photovoltaic cells 100 of the present invention further comprise a front contact electrode 106 (e.g., a transparent conductive oxide (TCO)) disposed on the photovoltaic module semiconductor 108. Exemplary materials for use as front contact electrode 106 are well known in the art and include tin oxide or zinc oxide. The compositions of the present invention also allow for manipulation of the front contact electrode (e.g., TCO). As the TCO layer is made thicker, its electrical conductance increases, while its transparency in the blue region of the spectrum decreases. Therefore, in the design of the photovoltaic cell, the final thickness is a compromise between power loss through sheet resistance of the TCO, and loss of blue photons due to absorption by the TCO. As the compositions of the present invention allow conversion of the blue photons of the spectrum to green, the TCO can be made thicker to reduce electrical resistance without the loss of current that would generally occur due to the loss of absorption of blue photons.

Suitably, the composition 102 comprising one or more colloidal metal nanoparticles, is disposed on the substantially transparent substrate 104 of the photovoltaic cell 100, opposite the front contact electrode 106. Suitably, substantially transparent substrate 104 comprises glass or a polymer. In further embodiments, the compositions 102 of the present invention can be disposed between the front contact electrode 106 and the transparent substrate 104 of the photovoltaic cell 100. In embodiments where CIGS materials are utilized, the compositions of the present invention are suitably disposed between the front contact electrode 106 and the transparent substrate 104 of the solar cell 100.

As described throughout, the interfaces between the hydrogenated amorphous silicon layers of photovoltaic module semiconductor 108 are substantially non-textured, including interfaces between the hydrogenated amorphous silicon layers, and interfaces between the hydrogenated amorphous silicon layers (as well as interfaces between the hydrogenated amorphous silicon layers and interfaces between the one or more hydrogenated microcrystalline or hydrogenated nanocrystalline silicon layers) and the electrodes of the photovoltaic cell (front and back contact).

Suitably, as shown in FIG. 1A, the photovoltaic cells further comprise a substantially transparent substrate 126 disposed on the composition 102 of colloidal metal nanoparticles 118.

As noted herein, the combination of colloidal metal nanoparticles and fluorescent nanoparticles provides enhanced conversion efficiency of the light that enters a photovoltaic cell. The fluorescent nanoparticles provide down-conversion of blue wavelengths of the solar spectrum to more efficiently absorbed green wavelengths, while the plasmonic scattering of the colloidal metal nanoparticles (suitably Ag nanoparticles), increases the path length of red photons through the photovoltaic cell. The colloidal metal nanoparticles can be configured to scatter more of the photons into the photovoltaic cell to increase absorbance (as opposed to isotropic scattering), including the photons that are produced by Foerster transfer.

The photovoltaic cells of the present invention can be combined with the same, similar, or different photovoltaic cells to prepare a photovoltaic module comprising a plurality of photovoltaic cells (see e.g., U.S. Pat. Nos. 5,143,556 and 5,164,020, the disclosures of which are incorporated by reference herein in their entireties, for examples of photovoltaic modules and arrays of photovoltaic cells). Such modules are suitably used to produce energy from solar light sources, for example, on houses, buildings, vehicles, etc., or in fields or other large areas where a large number of the photovoltaic cells can be arranged.

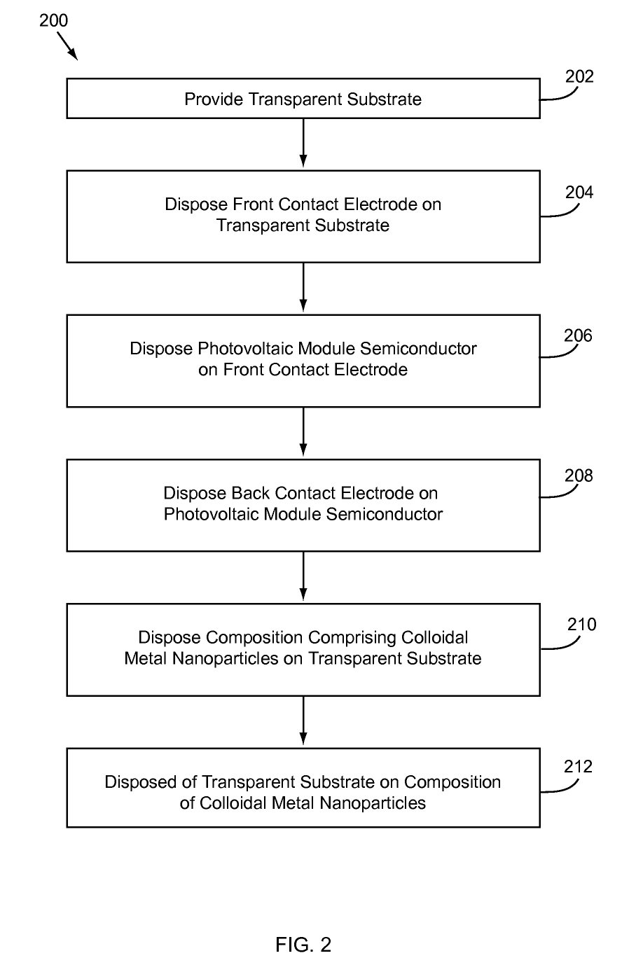

The present invention also provides methods of preparing a photovoltaic cell. As shown in FIG. 2, with reference to flowchart 200, and FIGS. 1A-1C, suitably such methods comprise step 202 of providing a substantially transparent substrate 104 (e.g., a glass or polymeric substrate). In step 204 of flowchart 200, a front contact electrode 106 is disposed on the substantially transparent substrate. In step 206, a photovoltaic module semiconductor 108 is disposed on the front contact electrode 106. As shown in flowchart 200, in step 208, a back contact electrode 110 is disposed on the photovoltaic module semiconductor. In step 210 of flowchart 200, a composition 102 comprising one or more colloidal metal nanoparticles 118, is disposed on the substantially transparent substrate 104 of the photovoltaic cell 100, opposite the front contact electrode 106. As described through, suitably the disposing in step 210 comprises disposing a composition further comprising one or more fluorescent nanoparticles.

Exemplary colloidal metallic nanoparticles, as well as sizes and shapes of the colloidal metallic nanoparticles are described throughout. Exemplary fluorescent nanoparticles, as well as core/shell compositions and sizes are also described throughout. Suitably, the colloidal metal nanoparticles and the fluorescent nanoparticles are in a single layer, though in other embodiments, the colloidal metal nanoparticles and the fluorescent nanoparticles are in one or more separate layers.

Suitably, the compositions of the present invention comprise colloidal metal nanoparticles encapsulated in a dielectric material, such as a spin-on-glass material. In further embodiments, as described herein, the disposing in step 210 comprises providing the colloidal metal nanoparticles with one or more ligands associated with each nanoparticle, and curing the ligand following the disposing, to generate a dielectric shell surrounding each nanoparticle.

Methods of disposing the compositions of the present invention are described herein and known in the art. Suitably, the disposing in step 210 comprises spin coating, ink jet printing, spraying or screen printing the composition. As described herein, suitably the fluorescent nanoparticles are disposed at a packing density such that an average distance between the fluorescent nanoparticles is less than, equal to, or greater than, a Foerster distance (R₀) of the fluorescent nanoparticle, an in further embodiments, the disposing comprises disposing the fluorescent nanoparticles and the metal nanoparticles at packing density such that an average distance between the fluorescent nanoparticles is less than, equal to, or greater than, a Foerster distance (R₀) of the fluorescent nanoparticles, and an average distance between the fluorescent nanoparticles and the metal nanoparticles is less than, equal to, or greater than, the Foerster distance (R₀) of the fluorescent nanoparticles.

Suitably, step 208 comprises disposing a back contact electrode comprises aluminum, tin oxide or zinc oxide, and step 204 comprises disposing a front contact electrode comprising a transparent conductive oxide layer, such as tin oxide or zinc oxide.

Step 206 of flowchart 200 suitably comprises disposing a photovoltaic module semiconductor 208 comprising one or more hydrogenated amorphous silicon layers, or one or more hydrogenated amorphous silicon layers and one or more hydrogenated microcrystalline or hydrogenated nanocrystalline silicon layers. Methods of disposing the photovoltaic module semiconductors are known in the art and include physical vapor deposition (PVD), chemical vapor deposition (CVD), plasma enhanced CVD (PECVD), etc. See U.S. Pat. 4,064,521, 4,718,947, 4,718,947 and 5,055,141. As described herein, the methods of the present invention suitably do not comprise texturing a surface of the silicon layers, either at interfaces between the various layers of the photovoltaic module semiconductor, or at interfaces between the photovoltaic module semiconductor and an electrode (e.g., a front electrode or a back electrode) of the photovoltaic cell. As described herein, eliminating a texturing step from the traditional photovoltaic cell manufacturing process reduces the time and expense required to prepare the cells. However, the surface can be textured if desired to further increase scattering.

As shown in flowchart 200, in step 212, the methods of the present invention can further comprise disposing a substantially transparent substrate 126 (e.g., a glass or polymeric substrate) on the composition of colloidal metal nanoparticles.

Exemplary embodiments of the present invention have been presented. The invention is not limited to these examples. These examples are presented herein for purposes of illustration, and not limitation. Alternatives (including equivalents, extensions, variations, deviations, etc., of those described herein) will be apparent to persons skilled in the relevant art(s) based on the teachings contained herein. Such alternatives fall within the scope and spirit of the invention.

All publications, patents and patent applications mentioned in this specification are herein incorporated by reference to the same extent as if each individual publication, patent or patent application was specifically and individually indicated to be incorporated by reference.

1. A composition comprising one or more colloidal metal nanoparticles, wherein the composition is disposed on a substantially transparent substrate of a photovoltaic cell.

2. The composition of claim 1, wherein the colloidal metal nanoparticles comprise Ag, Au, Cu or Al.

3. The composition of claim 2, wherein the colloidal metal nanoparticles comprise Ag colloidal nanoparticles.

4. The composition of claim 1, wherein the colloidal metal nanoparticles are about 50 nm to about 800 nm in size.

5. The composition of claim 4, wherein the colloidal metal nanoparticles are about 100 nm to about 800 nm in size.

6. The composition of claim 5, wherein the colloidal metal nanoparticles are about 200 nm to about 800 nm in size.

7. The composition of claim 1, wherein the colloidal metal nanoparticles are spherical, hemispherical, cylindrical or disk-shaped.

8. The composition of claim 1, wherein the composition comprises a dielectric material encapsulating the colloidal metal nanoparticles.

9. The composition of claim 8, wherein the dielectric material is a spin-on-glass material.

10. The composition of claim 1, wherein the composition further comprises one or more fluorescent nanoparticles.

11. The composition of claim 10, wherein the composition comprises a single layer comprising the colloidal metal nanoparticles and the fluorescent nanoparticles.

12. The composition of claim 10, wherein the composition comprises at least two layers, wherein the colloidal metal nanoparticles and the fluorescent nanoparticles are in separate layers.

13. The composition of claim 10, wherein the fluorescent nanoparticles are selected from the group consisting of CdSe, ZnSe, ZnTe and InP nanoparticles.

14. The composition of claim 13, wherein the fluorescent nanoparticles comprise a core selected from the group consisting of CdSe, ZnSe, ZnTe and InP, and a shell selected from the group consisting of ZnS and CdS surrounding the core.

15. The composition of claim 14, wherein the core is doped with Mn or Cu.

16. The composition of claim 14, wherein the core is about 1 nm to about 6 nm in size, and the shell is less than about 2 nm in thickness.

17. The composition of claim 16, wherein the shell is about 1 Å to about 10 Å in thickness.

18. The composition of claim 1, wherein the transparent substrate comprises glass.

19. The composition of claim 1, wherein the photovoltaic cell comprises one or more hydrogenated amorphous silicon layers.

20. The composition of claim 19, wherein interfaces between the hydrogenated amorphous silicon layers are substantially non-textured.

21. The composition of claim 19, wherein interfaces between the hydrogenated amorphous silicon layers, and interfaces between the one or more hydrogenated microcrystalline or hydrogenated nanocrystalline silicon layers, are substantially non-textured.

22. The composition of claim 1, wherein the photovoltaic cell comprises: one or more hydrogenated amorphous silicon layers; and
one or more hydrogenated microcrystalline or hydrogenated nanocrystalline silicon layers.

23. The composition of claim 22, wherein interfaces between the hydrogenated amorphous silicon layers, interfaces between the one or more hydrogenated microcrystalline or hydrogenated nanocrystalline silicon layers, and interfaces between the hydrogenated silicon layers and an electrode of the photovoltaic cell, are substantially non-textured.

24. The composition of claim 22, wherein interfaces between the hydrogenated amorphous silicon layers, and interfaces between the hydrogenated amorphous silicon layers and an electrode of the photovoltaic cell, are substantially non-textured.

25. The composition of claim 1, further comprising a substantially transparent substrate disposed on the composition of colloidal nanoparticles.

26. (canceled)

27. A method of preparing a composition comprising one or more colloidal metal nanoparticles on a substantially transparent substrate of a photovoltaic cell, the method comprising:
(a) providing a substantially transparent substrate; and
(b) disposing a composition comprising a dielectric material and colloidal metal nanoparticles on the substantially transparent substrate.

28-42. (canceled)

43. A method of preparing a photovoltaic cell, comprising:
(a) providing a substantially transparent substrate;
(b) disposing a front contact electrode on the substantially transparent substrate;
(c) disposing a photovoltaic module semiconductor on the front contact electrode;
(d) disposing a back contact electrode on the photovoltaic module semiconductor; and
(e) disposing a composition comprising one or more colloidal metal nanoparticles, on the substantially transparent substrate of the photovoltaic cell, opposite the front contact electrode.

44-50. (canceled)
